(19) United States
(12) Patent Application Publication
(10) Pub. No.: US 2026/0143969 A1
(43) Pub. Date: May 21, 2026

(54) PIEZOELECTRIC DEVICE USING STRETCHABLE PIEZOELECTRIC COMPOSITE AND METHOD FOR MANUFACTURING THE SAME

(71) Applicant: ELECTRONICS AND TELECOMMUNICATIONS RESEARCH INSTITUTE, Daejeon (KR)

(72) Inventors: Yun-Jeong KIM, Daejeon (KR); Hye-Jin KIM, Daejeon (KR); Sae-Rom SEO, Daejeon (KR)

(21) Appl. No.: 19/391,609

(22) Filed: Nov. 17, 2025

(30) Foreign Application Priority Data
Nov. 19, 2024 (KR) 10-2024-0165338
Nov. 10, 2025 (KR) 10-2025-0168450

(51) Int. Cl. H10N 30/85; H10N 30/045; H10N 30/077; H10N 30/092

(52) U.S. Cl. CPC H10N 30/852; H10N 30/045; H10N 30/077; H10N 30/092

(57) ABSTRACT

Disclosed herein are a piezoelectric device using a stretchable piezoelectric composite and a method for manufacturing the same. The piezoelectric device using the stretchable piezoelectric composite includes a piezoelectric film printed using the stretchable piezoelectric composite, and a substrate for fixing the piezoelectric film. The stretchable piezoelectric composite is produced by performing a sieving process of aligning piezoelectric nanoparticles, a functionalization process of improving interfacial adhesion by adding a functionalization agent to the aligned piezoelectric nanoparticles, and a mixing process in which the functionalized piezoelectric nanoparticles are mixed with a flexible and stretchable matrix.

### CROSS REFERENCE TO RELATED APPLICATIONS

This application claims the benefit of Korean Patent Application No. 10-2024-0165338, filed Nov. 19, 2024 and 10-2025-0168450, filed Nov. 10, 2025, which are hereby incorporated by reference in their entireties into this application.

### BACKGROUND OF THE INVENTION

### 1. Technical Field

The present disclosure relates generally to a piezoelectric device that maximizes piezoelectric characteristics using a stretchable piezoelectric composite and a process of manufacturing the piezoelectric device, and more particularly to a piezoelectric device that provides a stable electrical response even in various deformation environments, making it suitable for fields such as a wearable device and a body-attachable sensor.

### 2. Description of Related Art

Piezoelectric materials have generally been developed using ceramics such as PZT, but ceramics are hard and brittle, making them difficult to apply to a wearable device or a curved surface. That is, ceramic piezoelectric materials have a large thickness and lack physical flexibility, which limits their applicability in various fields.

To overcome these limitations, flexible polymer-based piezoelectric materials such as PVDF-TrFE have been developed. However, these materials exhibit low piezoelectric properties and poor durability, making them insufficient for fields requiring high performance. In particular, low piezoelectric sensitivity reduces efficiency during device manufacturing, and the materials are vulnerable to shocks or deformation, thereby limiting their practical applicability.

To address these problems, new piezoelectric materials with flexibility and stretchability, as shown in FIG. 1, have been developed by mixing piezoelectric nanoparticles with a flexible matrix. However, several technical challenges remain in this process. For example, piezoelectric nanoparticles tend to be non-uniformly dispersed within the matrix (agglomeration problem), leading to the low dispersion uniformity and degraded piezoelectric properties of the materials. Further, weak adhesion between the piezoelectric nanoparticles and the matrix reduces mechanical stability and durability, thereby limiting the manifestation of piezoelectric properties.

Further, research is being conducted on designing stretchable structures using structural deformation techniques, such as kirigami or origami, to secure stretchability in piezoelectric materials or films. However, these structural deformation approaches have limitations in that a hinge portion has low durability, making it vulnerable to repeated deformation, and miniaturization is difficult due to a large volume.

For these reasons, there is an increasing need for a piezoelectric composite material that inherently possesses tensile and stretchable properties.

### PRIOR ART DOCUMENTS

### Patent Documents

(Patent Document 1) Korean Patent Application Publication No. 10-2024-0092825, Date of Publication: Jun. 24, 2024 (Title: Piezoelectric composite fiber with improved piezoelectric performance, manufacturing method thereof, and flexible piezoelectric energy harvester comprising the same)

### SUMMARY OF THE INVENTION

Accordingly, the present disclosure has been made keeping in mind the above problems occurring in the prior art, and an object of the present disclosure is to enhance adhesion between piezoelectric nanoparticles and a flexible matrix using a surface treatment agent (hereinafter also referred to as a functionalization agent), and to overcome the weaknesses of conventional materials by producing a piezoelectric composite that secures both stretchability and tensile properties.

Another object of the present disclosure is to improve interfacial adhesion through surface modification treatment of piezoelectric nanoparticles, and to enhance both piezoelectric properties and durability through uniform dispersion, thereby maintaining stable performance even in repeated deformation environments.

A further object of the present disclosure is to provide a high-performance piezoelectric device that can be used in various fields.

Yet another object of the present disclosure is to allow a large-area film manufacturing process, thereby enabling reduction of a manufacturing process, and to implement an increase in piezoelectric properties according to a stretch ratio, thereby allowing various structural optimizations.

Still another object of the present disclosure is to enable the fabrication of sensor devices with various structures, such as a membrane and a windmill shape, using a stretchable piezoelectric material, thereby realizing high piezoelectric properties.

Still another object of the present disclosure is to provide a piezoelectric device that can be utilized as both a sensor and an actuator, and that can be applied to various fields by adjusting its resonant frequency and natural frequency.

In accordance with an aspect of the present disclosure to accomplish the above objects, there is provided a piezoelectric device using a stretchable piezoelectric composite, the device including a piezoelectric film printed using the stretchable piezoelectric composite, and a substrate for fixing the piezoelectric film. The stretchable piezoelectric composite is produced by performing a sieving process of aligning piezoelectric nanoparticles, a functionalization process of improving interfacial adhesion by adding a functionalization agent to the aligned piezoelectric nanoparticles, and a mixing process in which the functionalized piezoelectric nanoparticles are mixed with a flexible and stretchable matrix.

The functionalization agent may correspond to a functional material that improves interfacial interaction between the piezoelectric nanoparticles and the matrix, thereby enhancing adhesion.

The piezoelectric film may be fixed to the substrate by using either a direct printing method, in which the film is directly printed on an electrode and then attached to the substrate, or a film coating method, in which the film is printed on a carrier substrate and then the printed film is peeled off and coated onto a flexible electrode, a stretchable electrode, or the substrate.

The film coating method may peel off the film printed on the carrier substrate using a Laser Lift Off (LLO) process in which a laser is irradiated onto a surface of the carrier substrate where the film is not printed.

The film coating method may use a thermal compression method when the peeled film is coated onto the flexible electrode, the stretchable electrode, or the substrate.

The direct printing method and the film coating method each may further include a curing process of stabilizing the printed film in a solid state, and a poling process of aligning a polarization direction inside the film by an electric field.

The substrate may be made of a material and formed in a shape that is freely attachable to a flat or curved surface.

The functionalized piezoelectric nanoparticles and the matrix may be mixed according to a predetermined ratio in consideration of required piezoelectric properties.

In accordance with an aspect of the present disclosure to accomplish the above objects, there is provided a method of manufacturing a piezoelectric device using a stretchable piezoelectric composite, the method including a sieving process of aligning piezoelectric nanoparticles, a functionalization process of improving interfacial adhesion by adding a functionalization agent to the aligned piezoelectric nanoparticles, a mixing process of generating a stretchable piezoelectric composite by mixing the functionalized piezoelectric nanoparticles with a flexible and stretchable matrix, and a process of fixing a piezoelectric film printed using the stretchable piezoelectric composite to a substrate.

The functionalization agent may correspond to a functional material that improves interfacial interaction between the piezoelectric nanoparticles and the matrix, thereby enhancing adhesion.

The piezoelectric film may be fixed to the substrate by using either a direct printing method, in which the film is directly printed on an electrode and then attached to the substrate, or a film coating method, in which the film is printed on a carrier substrate and then the printed film is peeled off and coated onto a flexible electrode, a stretchable electrode, or the substrate.

The film coating method may peel off the film printed on the carrier substrate using a Laser Lift Off (LLO) process in which a laser is irradiated onto a surface of the carrier substrate where the film is not printed.

The film coating method may use a thermal compression method when the peeled film is coated onto the flexible electrode, the stretchable electrode, or the substrate.

The direct printing method and the film coating method each may further include a curing process of stabilizing the printed film in a solid state, and a poling process of aligning a polarization direction inside the film by an electric field.

The substrate may be made of a material and formed in a shape that is freely attachable to a flat or curved surface.

The functionalized piezoelectric nanoparticles and the matrix may be mixed according to a predetermined ratio in consideration of required piezoelectric properties.

### BRIEF DESCRIPTION OF THE DRAWINGS

The above and other objects, features and advantages of the present disclosure will be more clearly understood from the following detailed description taken in conjunction with the accompanying drawings, in which:

FIG. 1 is a diagram illustrating the flexibility and stretchability of a material;

FIG. 2 is an operation flowchart showing a method for manufacturing a piezoelectric device using a stretchable piezoelectric composite according to an embodiment of the present disclosure;

FIG. 3 is a diagram illustrating an example of a sieving process, a functionalization process, and a mixing process according to the present disclosure;

FIG. 4 is a diagram illustrating an example comparing a slurry, a film surface, and a post-printing image depending on the presence or absence of a functionalization agent according to the present disclosure;

FIG. 5 is a diagram illustrating an example of an image of the stretchable piezoelectric composite during bending, depending on the presence or absence of the functionalization agent according to the present disclosure;

FIGS. 6 and 7 are diagrams illustrating examples of SEM images of an interface between ceramic particles and a binder, depending on the presence or absence of the functionalization agent according to the present disclosure;

FIG. 8 is a diagram illustrating an example comparing a dielectric loss depending on the presence or absence of the functionalization agent according to the present disclosure;

FIGS. 9 and 10 are diagrams illustrating an example of a stretchable piezoelectric composite produced by a film coating method according to the present disclosure;

FIGS. 11 and 12 are diagrams illustrating examples of FEA results (piezo potential and Von Mises stress) based on the degree of dispersion depending on the presence or absence of the functionalization agent according to the present disclosure;

FIG. 13 is a diagram illustrating an example of FEA results (piezo potential and Von Mises stress) based on the degree of stretchability depending on the presence or absence of the functionalization agent according to the present disclosure;

FIG. 14 is a detailed view illustrating the manufacturing process of a piezoelectric device using the stretchable piezoelectric composite according to the present disclosure;

FIG. 15 is a diagram illustrating an example of a LLO process according to the present disclosure;

FIG. 16 is a diagram illustrating an example of OM and confocal images depending on the presence or absence of a thermal compression process according to the present disclosure;

FIG. 17 is a diagram illustrating an example of a piezoelectric voltage coefficient depending on the presence or absence of the functionalization agent according to the present disclosure; and

FIGS. 18 and 19 are diagrams illustrating piezoelectric devices using the stretchable piezoelectric composite according to an embodiment of the present disclosure.

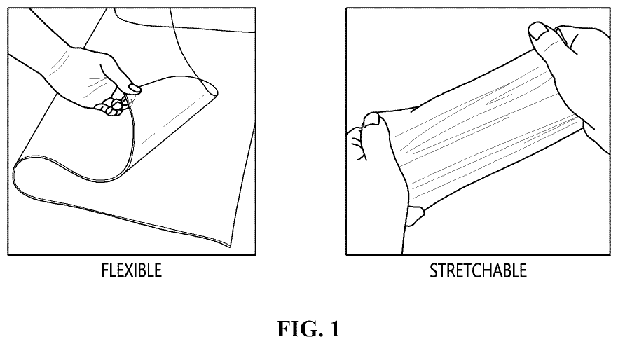

### DESCRIPTION OF THE PREFERRED EMBODIMENTS

The present disclosure will be described in detail below with reference to the accompanying drawings. Repeated descriptions and descriptions of known functions and configurations which have been deemed to make the gist of the present disclosure unnecessarily obscure will be omitted below. The embodiments of the present disclosure are intended to fully describe the present disclosure to a person having ordinary knowledge in the art to which the present disclosure pertains. Accordingly, the shapes, sizes, etc. of components in the drawings may be exaggerated to make the description clearer.

In the present specification, each of phrases such as “A or B”, “at least one of A and B”, “at least one of A or B”, “A, B, or C”, “at least one of A, B, and C”, and “at least one of A, B, or C” may include any one of the items enumerated together in the corresponding phrase, among the phrases, or all possible combinations thereof.

Hereinafter, embodiments of the present disclosure will be described in detail with reference to the attached drawings.

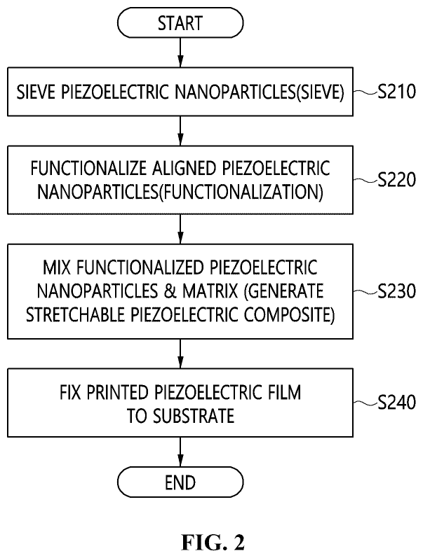

FIG. 2 is an operation flowchart illustrating a method for manufacturing a piezoelectric device using a stretchable piezoelectric composite according to an embodiment of the present disclosure.

Referring to FIG. 2, the method for manufacturing the piezoelectric device using the stretchable piezoelectric composite according to an embodiment of the present disclosure performs a sieving process S210 to align piezoelectric nanoparticles.

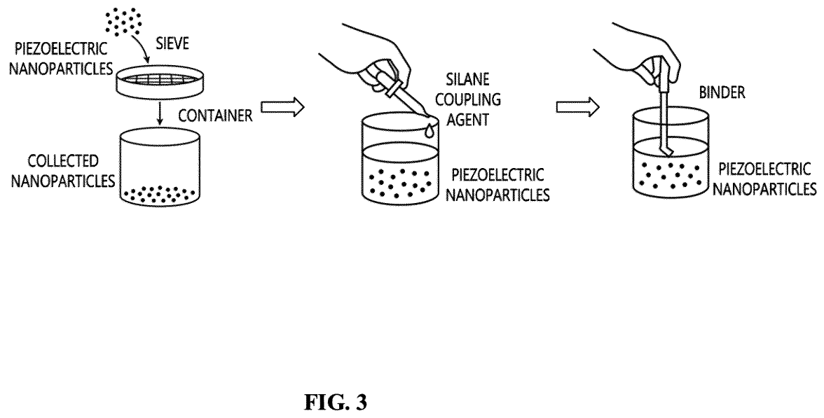

In this case, the sieving process may refer to a process of separating or aligning particles by size. For example, as shown in the first illustration of FIG. 3, the piezoelectric nanoparticles may be aligned using a sieve or a classifier.

Further, the method for manufacturing the piezoelectric device using the stretchable piezoelectric composite according to an embodiment of the present disclosure performs surface treatment (hereinafter referred to as functionalization) S220 by adding a functionalization agent to the aligned piezoelectric nanoparticles so as to improve interfacial adhesion.

In this case, the functionalization process may refer to a process that chemically or physically modifies the surface properties of the material to control interfacial adhesion. For example, as shown in the second illustration of FIG. 3, the functionalization may be performed by adding the functionalization agent to the aligned piezoelectric nanoparticles.

That is, by adding the functionalization agent, the adhesion between the piezoelectric nanoparticles and a matrix can be improved.

For example, the functionalization agent may be applied to piezoelectric nanoparticles including ceramic piezoelectric materials such as Lead Zirconate Titanate (PZT), Barium Titanate (BTO), and Barium Zirconia Titanate (BZT). The functionalization agent may also be applied to piezoelectric nanoparticles that have been doped and thereby exhibit modified surface properties.

In this case, the ratio between the functionalization agent and the piezoelectric nanoparticles may be configured in various combinations, and the piezoelectric properties may be maximized through heat treatment and stirring processes.

Further, the method for manufacturing the piezoelectric device using the stretchable piezoelectric composite according to an embodiment of the present disclosure performs a mixing process S230 in which the functionalized piezoelectric nanoparticles are mixed with a flexible and stretchable matrix to produce a stretchable piezoelectric composite.

In this case, the mixing process may refer to a process of mixing the piezoelectric nanoparticles with a polymer matrix to fabricate the piezoelectric nanoparticles into an actual device form. For example, as shown in the third illustration of FIG. 3, the functionalized piezoelectric nanoparticles may be mixed with the matrix.

In this case, in the mixing process, uniform mixing may be achieved by using methods such as a planetary mixer, a three-roll mixer, sonication, or a grinding mixer.

In this case, depending on whether the functionalization with the functionalization agent is performed or not, the viscosity of the stretchable piezoelectric composite (slurry) and the surface characteristics of the film may vary, thereby controlling the quality and piezoelectric properties of the film.

For example, FIG. 4 illustrates slurry viscosities 411 and 421, film surfaces 412 and 422, and roughness 413 and 423 after film printing, depending on the presence or absence of functionalization according to the present disclosure. Comparing a non-functionalized image 410 and a functionalized image 420 shown in FIG. 4, it can be seen that the slurry mixed with the functionalization agent is uniformly dispersed (422) without aggregation of the piezoelectric nanoparticles, exhibits an appropriate viscosity (421) during printing, and suppresses crack formation in the film while reducing the surface roughness of the film (423).

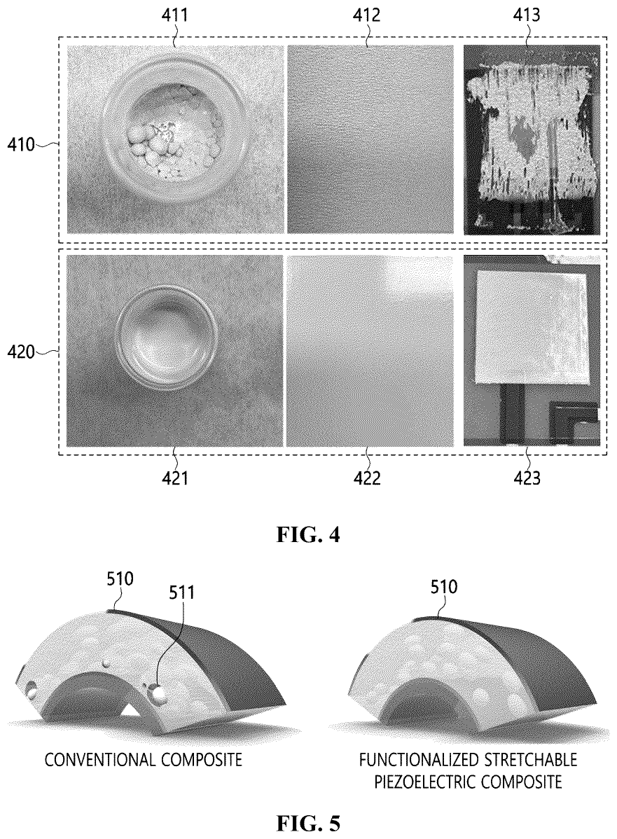

Further, referring to FIG. 5, a piezoelectric composite 510 fabricated without the functionalization process may exhibit voids 511 or defects during stretching or bending, resulting in reduced durability. However, a stretchable piezoelectric composite 520 fabricated through the functionalization process according to the present disclosure may be stably deformed without voids or defects even during stretching or bending, thereby exhibiting high durability.

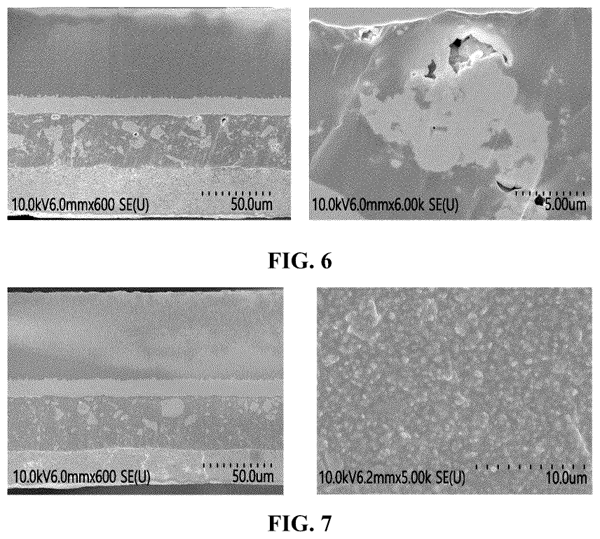

This can also be seen through examples of SEM (Scanning Electron Microscope) images of interfaces between ceramic particles and binder, depending on the presence or absence of the functionalization agent, as shown in FIGS. 6 and 7.

FIG. 6 shows the SEM image of the interface between the ceramic particles and the binder without the addition of the functionalization agent, and FIG. 7 shows the SEM image of the interface between the ceramic particles and the binder with the addition of the functionalization agent. When comparing the SEM images of the two figures, it can be seen that the image in FIG. 6 exhibits many voids and defects, whereas the image in FIG. 7 shows relatively fewer voids and defects.

Further, the functionalization process according to the present disclosure can significantly enhance the piezoelectric properties by reducing a dielectric loss by more than 80%.

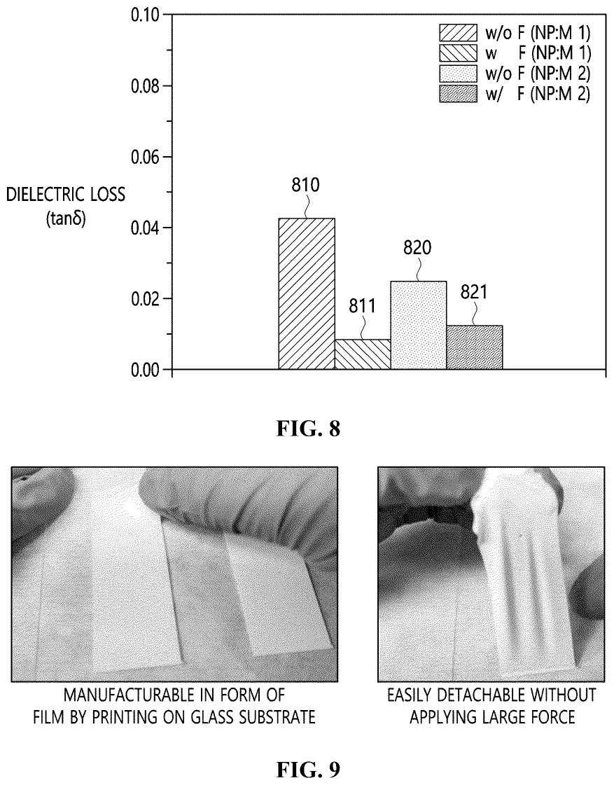

For example, FIG. 8 is a diagram illustrating an example comparing the dielectric loss depending on the presence or absence of the functionalization agent according to the present disclosure. Graphs 810 and 811 represent the dielectric loss under the same conditions except for the presence or absence of the functionalization process, and graphs 820 and 821 likewise represent the dielectric loss under the same conditions except for the presence or absence of the functionalization process. In this case, the graphs 810 and 820 represent the dielectric loss in the case where the functionalization process is not performed, while the graphs 811 and 821 represent the dielectric loss in the case where the functionalization process is performed. That is, it can be observed that the dielectric loss is significantly reduced when the functionalization process is applied.

In this case, the functionalization agent may correspond to a functional material that improves interfacial interaction between the piezoelectric nanoparticles and the matrix, thereby enhancing adhesion.

For example, as the functionalization agent, silane-based, phosphonic acid-based, carboxylic acid-based, or methacrylate-based materials may be used.

In this case, the functionalized piezoelectric nanoparticles and the matrix may be mixed according to a predetermined ratio in consideration of the required piezoelectric properties.

Further, the method for manufacturing the piezoelectric device using the stretchable piezoelectric composite according to an embodiment of the present disclosure performs a fixing process S240 in which the piezoelectric film printed using the stretchable piezoelectric composite is fixed to the substrate.

In this case, the piezoelectric film may be fixed onto the substrate by either a direct printing method, in which the film is directly printed on an electrode and then attached to the substrate, or a film coating method, in which the film is printed on a carrier substrate and then the printed film is peeled off and coated onto a flexible electrode, stretchable electrode, or substrate.

For example, the stretchable piezoelectric composite slurry manufactured according to the present disclosure may be directly printed onto the electrode or coated onto the carrier substrate to be formed into a film.

In this case, the direct printing method and the film coating method may each further include a curing process of stabilizing the printed film in a solid state, and a poling process of aligning the polarization direction inside the film by an electric field.

For example, the direct printing method of printing directly onto the electrode may be mainly classified into two methods. A first method involves directly printing the slurry onto the electrode or in the form of a film through processes such as tape casting, screen printing, or roll-to-roll processing, followed by curing at room temperature or by heat treatment, and then performing poling. A second method involves printing directly onto the electrode or in the form of a film, as in the first method, and performing curing at room temperature or heat treatment simultaneously with the poling process. By carrying out curing and poling simultaneously, domains can be more efficiently aligned by the electric field, thereby maximizing the piezoelectric properties.

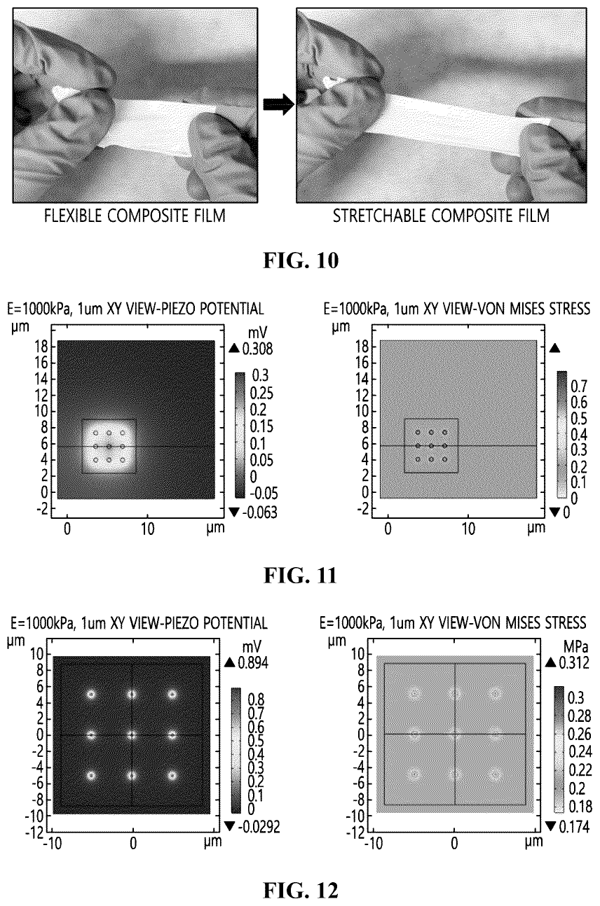

In this case, as shown in FIG. 9, the film coating method of coating onto the carrier substrate involves printing the film onto a separate carrier substrate (such as a glass substrate), curing it, and then peeling it off from the substrate. This method may include a process of applying a release agent to the substrate before printing and a Laser Lift Off (LLO) process. The resulting film may possess both flexibility and stretchability simultaneously, as shown in FIG. 10.

In this case, in the film coating method, the film printed on the carrier substrate may be peeled off by using the LLO process, in which a laser is irradiated onto the surface of the carrier substrate where the film is not printed.

At this time, the film coating method may use a thermal compression method when the peeled film is coated onto the flexible electrode, the stretchable electrode, or the substrate.

For example, the film fabricated by the film coating method may be patterned into a desired shape using scissors, a knife, or a laser, and may be attached to the electrode or a desired attachment position using an adhesive or a thermal compression process.

The stretchable piezoelectric composite film completed in this manner according to the present disclosure has both flexibility and stretchability, and unlike conventional flexible piezoelectric films, can be utilized in various environments and has advantages in optimizing piezoelectric properties.

For example, FIGS. 11 and 12 illustrate examples of the results (piezo potential and Von Mises stress) of Finite Element Analysis (FEA) based on the degree of dispersion depending on the presence or absence of the functionalization agent according to the present disclosure, showing the piezoelectric potential and Von Mises stress depending on the presence or absence of the functionalization agent.

In this case, FIG. 11 represents a case without the application of the functionalization agent, while FIG. 12 represents a case with the application of the functionalization agent. That is, when comparing FIGS. 11 and 12, it can be seen that the higher the degree of dispersion between the piezoelectric nanoparticles and the matrix achieved by applying the functionalization agent, the more uniformly the piezoelectric potential and Von Mises stress are distributed throughout the film when an external force is applied to the film. This may indicate that the same output voltage can be generated regardless of where the film is pressed, stretched, or subjected to external force.

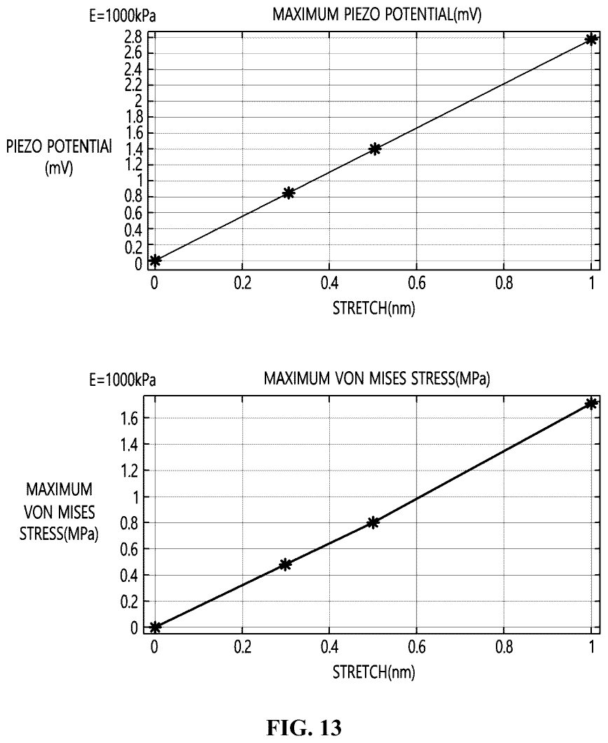

Further, FIG. 13 illustrates an example of FEA results (piezo potential and Von Mises stress) based on the degree of stretchability depending on the presence or absence of the functionalization agent according to the present disclosure. Referring to FIG. 13, it can be seen that as the film is stretched, both the piezoelectric potential and the Von Mises stress increase. In this case, the natural frequency may increase or decrease depending on the conditions even when using an actuator.

Through the FEA results shown in FIGS. 11 to 13, it can be seen that the composite using the functionalization agent exhibits a uniform distribution of piezoelectric properties and stress throughout the film, thereby satisfying both stability and durability.

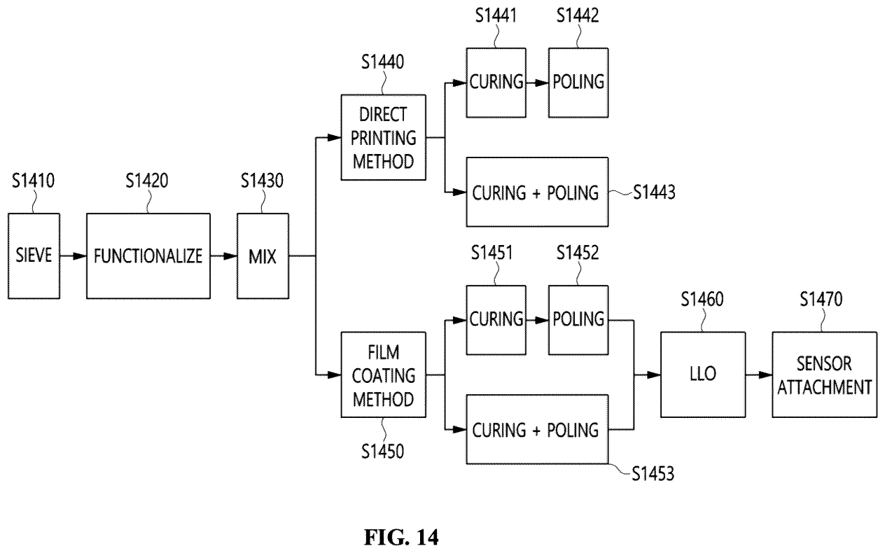

Further, the above-described manufacturing process may be classified in detail as illustrated in FIG. 14.

For example, referring to FIG. 14, in the manufacturing process of the piezoelectric device using the stretchable piezoelectric composite according to the present disclosure, the piezoelectric nanoparticles are first refined through a sieving process S1410, and then the functionalization agent is added at step S1420 to enhance interfacial adhesion, thereby optimizing dispersion. Subsequently, the functionalized piezoelectric nanoparticles may be mixed in various ratios with flexible and stretchable matrices such as PDMS, Ecoflex, Clear-Flex, or Vyta at step S1430 to produce the stretchable piezoelectric composite.

If the direct printing method is used at step S1440, the film may be directly printed onto the electrode, followed by curing at room temperature or by heat treatment at step S1441, and then subjected to a poling process S1442. In this case, the poling process may also be performed simultaneously with the room-temperature curing or heat treatment process at step S1443.

If the film coating method is used at step S1450, printing may be performed in the form of a film on a separate carrier substrate, followed by curing at room temperature or by heat treatment at step S1451, and then subjected to a poling process S1452. In this case, the poling process may also be performed simultaneously with the room-temperature curing or heat treatment process at step S1453. Thereafter, the film may be peeled off from the carrier substrate through an LLO process S1460, and then the peeled film may be attached to a sensor intended for use at step S1470.

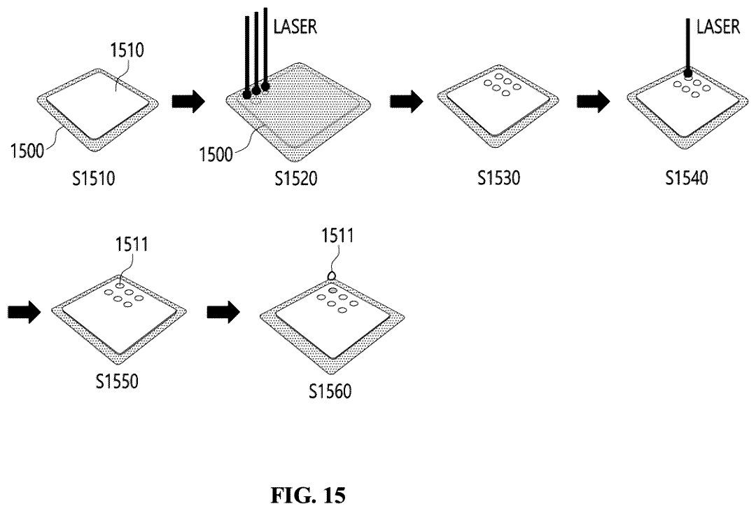

The present disclosure has the effect of reducing manufacturing process costs because it enables a large-area process at a low temperature. In this case, the process of transferring the printed composite film may be referred to in FIG. 15.

Referring to FIG. 15, a stretchable piezoelectric composite film 1510 may be first formed on a carrier substrate 1500 or on a substrate coated with a sacrificial layer at step S1510.

Thereafter, a laser may be irradiated onto an entire back surface of the stretchable piezoelectric composite film 1510 at step S1520 to peel the stretchable piezoelectric composite film 1510 from the carrier substrate 1500 at step S1530.

Thereafter, the entire stretchable piezoelectric composite film 1510 may be peeled and utilized over a large area, or the front surface of the film may be laser-traced into a desired shape at step S1540, allowing a film 1511 of a desired shape to be cut out from the stretchable piezoelectric composite film 1510 for use at steps S1550 and S1560.

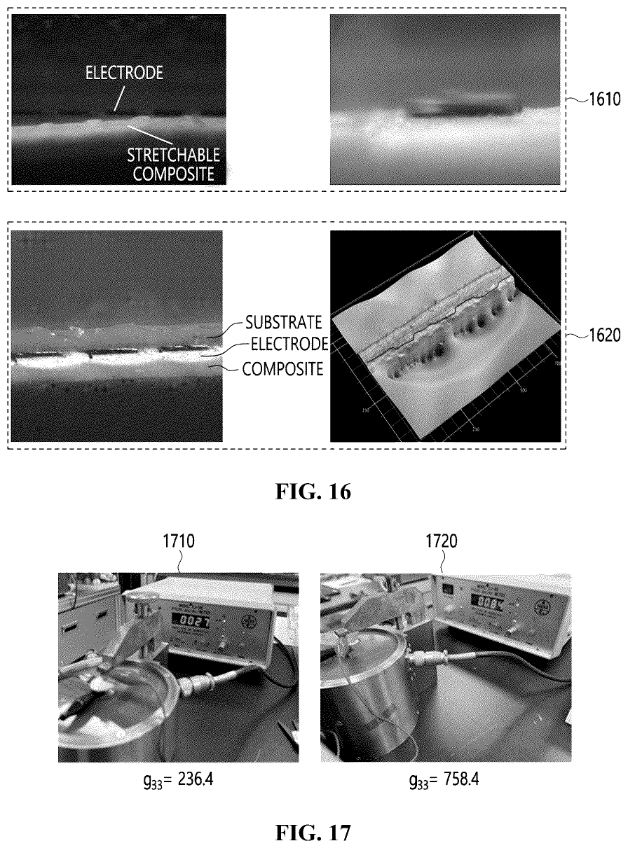

Further, FIG. 16 illustrates an example of OM and confocal images depending on the presence or absence of the thermal compression process according to the present disclosure. The figure shows optical microscopy (OM) images for observing the cross-section or interfacial structure of a sample, as well as confocal laser scanning microscopy images for observing a 3D interfacial structure in a depth direction.

In this case, in images corresponding to simple bonding 1610 and thermal compression bonding 1620, the interfacial bonding state and adhesion between the substrate, electrode, and stretchable piezoelectric composite may be visually confirmed. That is, when comparing two images obtained through the optical microscopy (OM), it can be observed that the image from the thermal compression bonding 1620 shows a clearer interfacial boundary and more uniform adhesion than the image from the simple bonding 1610. Furthermore, when the image from the thermal compression bonding 1620 is observed using the confocal laser scanning microscopy, it can be confirmed that no significant micro-defects or voids are present.

Further, FIG. 17 illustrates an example of a piezoelectric voltage coefficient depending on the presence or absence of the functionalization agent according to the present disclosure, where a g₃₃ coefficient shown in FIG. 17 may represent the piezoelectric voltage coefficient. That is, a larger g₃₃ coefficient may indicate that the electric field is more effectively generated by applied pressure.

FIG. 17 shows a case 1710 where no functionalization agent is applied and a case 1720 where the functionalization agent is applied, when all conditions of the piezoelectric device are identical.

Therefore, according to the results shown in FIG. 17, it can be confirmed that the piezoelectric device in the case 1720 where the functionalization agent is applied exhibits higher piezoelectric performance than the piezoelectric device in the case 1710 where the functionalization agent is not applied.

In this case, the substrate may be made of a material and formed in a shape that may be freely attached to either a flat or curved surface.

For example, the stretchable piezoelectric composite film manufactured according to the present disclosure is made of a flexible and stretchable material, and allows adjustment of various parameters, so that it can be designed into various structures such as spacers, membranes, and wind turbine blades. Through this, the characteristics of the piezoelectric device can be optimized, or its resonant frequency and natural frequency can be adjusted, thereby enabling it to be applied to various fields as a sensor or an actuator.

Through the manufacturing method of the piezoelectric device using such a stretchable piezoelectric composite, it is possible to realize stable piezoelectric performance even in various deformation environments by using the flexible and stretchable piezoelectric composite that overcomes the physical limitations of conventional piezoelectric materials.

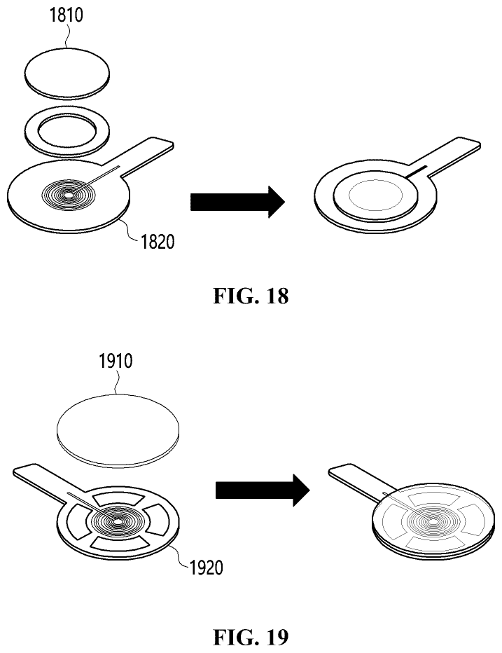

FIGS. 18 and 19 are diagrams illustrating piezoelectric devices using the stretchable piezoelectric composite according to an embodiment of the present disclosure.

Referring to FIGS. 18 and 19, the piezoelectric device using the stretchable piezoelectric composite according to an embodiment of the present disclosure includes a piezoelectric film 1910 printed using the stretchable piezoelectric composite and a substrate 1920 for fixing the piezoelectric film 1910.

In this case, the stretchable piezoelectric composite may be produced by performing a sieving process of aligning piezoelectric nanoparticles, a functionalization process of improving interfacial adhesion by adding a functionalization agent to the aligned piezoelectric nanoparticles, and a mixing process in which the functionalized piezoelectric nanoparticles are mixed with a flexible and stretchable matrix.

In this case, the functionalization agent may correspond to a functional material that improves interfacial interaction between the piezoelectric nanoparticles and the matrix, thereby enhancing adhesion.

For example, silane-based, phosphonic acid-based, carboxylic acid-based, or methacrylate-based materials may be used as the functionalization agent.

In this case, the piezoelectric film may be fixed onto the substrate by either the direct printing method, in which the film is directly printed on the electrode and then attached to the substrate, or the film coating method, in which the film is printed on the carrier substrate and then the printed film is peeled off and coated onto the flexible electrode, stretchable electrode, or substrate.

In this case, in the film coating method, the film printed on the carrier substrate may be peeled off by using the LLO process, in which the laser is irradiated onto the surface of the carrier substrate where the film is not printed.

At this time, the film coating method may use a thermal compression method when the peeled film is coated onto the flexible electrode, the stretchable electrode, or the substrate.

In this case, the direct printing method and the film coating method may each further include a curing process of stabilizing the printed film in a solid state, and a poling process of aligning the polarization direction inside the film by an electric field.

In this case, the substrates 1820 or 1920 may be made of a material and formed in a shape that may be freely attached to a flat or curved surface.

In this case, the functionalized piezoelectric nanoparticles and the matrix may be mixed according to a predetermined ratio in consideration of the required piezoelectric properties.

Since the components of the piezoelectric device have been described in detail through the process of manufacturing the piezoelectric device shown in FIG. 2, a detailed description thereof will be omitted in connection with this drawing.

Here, FIG. 18 illustrates an example of a membrane-structured piezoelectric device according to the present disclosure, and FIG. 19 illustrates an example of a windmill-structured piezoelectric device according to the present disclosure. That is, the drawings shown in FIGS. 18 and 19 correspond merely to exemplary embodiments and may be applied to various forms and environments.

For example, since the piezoelectric film according to the present disclosure is flexible and stretchable, it can be applied to various fields such as wearable devices or body-attachable sensors that require miniaturization and weight reduction. Further, because the piezoelectric properties can be optimized according to specific conditions and requirements, it can also be applied to customized sensors or actuators.

According to the present disclosure, stable piezoelectric performance can be achieved even in various deformation environments by using a flexible and stretchable piezoelectric composite that overcomes the physical limitations of conventional piezoelectric materials.

Further, the present disclosure can maximize piezoelectric properties and durability and ensure uniform quality by improving interfacial adhesion between the piezoelectric nanoparticles and the matrix and suppressing agglomeration through the use of a functionalization agent.

Furthermore, the present disclosure enables large-area film fabrication through a simple process and low-temperature conditions, thereby allowing mass production of films and reducing manufacturing costs.

Furthermore, the present disclosure can provide a piezoelectric material suitable for various fields, such as wearable devices or body-attachable sensors that require miniaturization and weight reduction, through precise control of structural parameters.

Furthermore, the present disclosure can provide advantageous benefits for the development of customized sensors and actuators by optimizing piezoelectric properties according to specific conditions and requirements.

As described above, in the piezoelectric device using the stretchable piezoelectric composite and method of manufacturing the piezoelectric device according to the present disclosure, the configurations and schemes in the above-described embodiments are not limitedly applied, and some or all of the above embodiments can be selectively combined and configured such that various modifications are possible.

What is claimed is:

1. A piezoelectric device using a stretchable piezoelectric composite, the piezoelectric device comprising:
a piezoelectric film printed using the stretchable piezoelectric composite; and
a substrate configured to fix the piezoelectric film,
wherein the stretchable piezoelectric composite is produced by performing a sieving process of aligning piezoelectric nanoparticles, a functionalization process of improving interfacial adhesion by adding a functionalization agent to the aligned piezoelectric nanoparticles, and a mixing process in which the functionalized piezoelectric nanoparticles are mixed with a flexible and stretchable matrix.

2. The piezoelectric device of claim 1, wherein the functionalization agent corresponds to a functional material that improves interfacial interaction between the piezoelectric nanoparticles and the matrix, thereby enhancing adhesion.

3. The piezoelectric device of claim 1, wherein the piezoelectric film is fixed to the substrate by using either a direct printing method, in which the film is directly printed on an electrode and then attached to the substrate, or a film coating method, in which the film is printed on a carrier substrate and then the printed film is peeled off and coated onto a flexible electrode, a stretchable electrode, or the substrate.

4. The piezoelectric device of claim 3, wherein the film coating method peels off the film printed on the carrier substrate using a Laser Lift Off (LLO) process in which a laser is irradiated onto a surface of the carrier substrate where the film is not printed.

5. The piezoelectric device of claim 3, wherein the film coating method uses a thermal compression method when the peeled film is coated onto the flexible electrode, the stretchable electrode, or the substrate.

6. The piezoelectric device of claim 3, wherein the direct printing method and the film coating method each further comprise a curing process of stabilizing the printed film in a solid state, and a poling process of aligning a polarization direction inside the film by an electric field.

7. The piezoelectric device of claim 1, wherein the substrate is made of a material and formed in a shape that is freely attachable to a flat or curved surface.

8. The piezoelectric device of claim 1, wherein the functionalized piezoelectric nanoparticles and the matrix are mixed according to a predetermined ratio in consideration of required piezoelectric properties.

9. A method for manufacturing a piezoelectric device using a stretchable piezoelectric composite, the method comprising:
a sieving process of aligning piezoelectric nanoparticles;
a functionalization process of improving interfacial adhesion by adding a functionalization agent to the aligned piezoelectric nanoparticles;
a mixing process of generating a stretchable piezoelectric composite by mixing the functionalized piezoelectric nanoparticles with a flexible and stretchable matrix; and
a process of fixing a piezoelectric film printed using the stretchable piezoelectric composite to a substrate.

10. The method of claim 9, wherein the functionalization agent corresponds to a functional material that improves interfacial interaction between the piezoelectric nanoparticles and the matrix, thereby enhancing adhesion.

11. The method of claim 9, wherein the piezoelectric film is fixed to the substrate by using either a direct printing method, in which the film is directly printed on an electrode and then attached to the substrate, or a film coating method, in which the film is printed on a carrier substrate and then the printed film is peeled off and coated onto a flexible electrode, a stretchable electrode, or the substrate.

12. The method of claim 11, wherein the film coating method peels off the film printed on the carrier substrate using a Laser Lift Off (LLO) process in which a laser is irradiated onto a surface of the carrier substrate where the film is not printed.

13. The method of claim 11, wherein the film coating method uses a thermal compression method when the peeled film is coated onto the flexible electrode, the stretchable electrode, or the substrate.

14. The method of claim 11, wherein the direct printing method and the film coating method each further comprise a curing process of stabilizing the printed film in a solid state, and a poling process of aligning a polarization direction inside the film by an electric field.

15. The method of claim 9, wherein the substrate is made of a material and formed in a shape that is freely attachable to a flat or curved surface.

16. The method of claim 9, wherein the functionalized piezoelectric nanoparticles and the matrix are mixed according to a predetermined ratio in consideration of required piezoelectric properties.
